(19) United States
(12) Patent Application Publication
(10) Pub. No.: US 2005/0087673 A1
(43) Pub. Date: Apr. 28, 2005

(54) Apparatus and method for an electronically tuned, wavelength-dependent optical detector

(76) Inventors: Ray Chen, Stanford, CA (US); David A.B. Miller, Stanford, CA (US)

Correspondence Address: LUMEN INTELLECTUAL PROPERTY SERVICES, INC., 2345 YALE STREET, 2ND FLOOR, PALO ALTO, CA, 94306, US

(21) Appl. No.: 10/693,652

(22) Filed: Oct. 23, 2003

(51) Int. Cl. H01L 31/00

(52) U.S. Cl. 250/214.1

(57) ABSTRACT

An apparatus and method for an electronically tuned, wavelength-dependent optical detector are disclosed. The electronically tuned, wavelength-dependent optical detector is a modified metal-semiconductor-metal photodetector comprising a comb-like metal electrode at a common voltage and metal electrodes each supplied with a control voltage by a voltage means. The wavelength to be detected in a stream of light illuminating the electronically tuned, wavelength-dependent optical detector is selected based on the set of control voltages applied to the metal electrodes using the voltage means and the relative position of the electronically tuned, wavelength-dependent optical detector. In another embodiment of the invention, the wavelength to be detected with the electronically tuned, wavelength-dependent optical detector is also selected using a standing wave generator, such as an interferometer, to produce a spatially varying light intensity on the surface of the electronically tuned, wavelength-dependent optical detector.

### FIELD OF THE INVENTION

The present invention relates generally to an apparatus and method for an electronically tuned, wavelength-dependent optical detector.

### BACKGROUND OF THE INVENTION

Wavelength-dependent optical detectors are essential optical components that are incorporated in a myriad of applications including spectrometers, optical interconnects and optical communications systems.

An existing wavelength-dependent optical detector is the so-called metal-semiconductor-metal (MSM) photodetector. In this device, an interdigitated pair of metal electrodes is deposited on a surface of a semiconductor. Light illuminating the MSM device is absorbed in the semiconductor producing charge carriers that drift to the neighboring metal electrodes when a voltage is applied to the metal electrodes. The resulting light-induced current is amplified and detected by an amplifier. The wavelength-dependence of the MSM device is partially determined by the absorption characteristics of the semiconductor in the MSM device. GaAs is used as the semiconductor for MSM devices in the 800 nm wavelength range. InAlAs deposited on InGaAs is used as the semiconductor for MSM devices in the 1600 nm wavelength range. The prior art teaches that the wavelength-dependence of the MSM device can be further selected by creating a standing wave on the MSM detector and fabricating the MSM device such that metal electrodes have a particular spacing, for example, a quarter of the wavelength of light to be detected.

While such MSM devices have been successfully employed in a variety of applications, a principal limitation of the MSM device is that the wavelength-dependence cannot be dynamically tuned. It is manifest that this is also the case for other optical detectors that are not wavelength-dependent, such as photodiodes and photomultiplier tubes. Prior art solutions to this technical challenge include external means for dynamically tuning the wavelength of light detected. Solutions include monochromators, interferometers, multiplexers/demultiplexers, spatial optical filters, spectral optical filters (including cavity resonators) and diffraction gratings. For example, see U.S. Pat. Nos. 6,583,900, 6,594,410 and 6,597,841. However, the speed with which the selected wavelength can be changed in these approaches is limited when the dynamic tuning is based on mechanical motion, such as that associated with a stepper motor or thermal expansion. This is also the case when the dynamic tuning is based on the propagation of waves (for example, sound) in a medium, such as in an acousto-optic modulator or a dynamic diffraction grating. The response time for dynamic tuning of the wavelength-dependence of the existing optical detectors in conjunction with such external means is substantially longer than a microsecond and is typically hundreds to thousands of microseconds. A PIN detector with multiple quantum wells can be dynamically tuned with a fast response time; however, such devices only have a coarse tuning capability over a small range of wavelengths and require a large biasing voltage. These limitations in the dynamic tuning of the wavelength dependence of existing optical detectors are particularly problematic in existing or proposed optical communications systems based on Wavelength Division Multiplexing (WDM).

In optical communications systems based on WDM, a combination of time dependent multiplexing (interleaved packets of information), frequency dependent multiplexing (information communicated using multiple, different wavelengths) and/or spread spectrum (wideband) encoding techniques such as code division multiple access are used. Systems include coarse wavelength division multiplexing (CWDM) and dense wavelength division multiplexing (DWDM). Recent proposals include 80 channels utilizing a wavelength range centered around 1550 nm (193,300 GHz) with a channel spacing of approximately 0.4 nm (50 GHz) and optical packets of information spaced on time scales on the order of nanoseconds. Future systems will employ more channels (smaller channel spacing) and packets of information spaced on shorter time scales.

To be useful in detecting packets of information based on wavelength in a WDM system, it is highly desirable to be able to switch the wavelength dependence of the optical detector on times scales on the order of or less than the length of the optical packets of information. This necessitates response times for dynamic tuning of the wavelength dependence of the optical detector of a few nanoseconds or less. Response times of this order are well beyond the capability of most of the existing solutions. The alternative, involving a plurality of wavelength-dependent optical detectors with slow dynamic tuning response times, would be expensive and difficult to manufacture and maintain. Each wavelength in the optical system would require a separate detector, the related electronics for amplifying detected signals, as well as a fixed optical filter capable of resolving the small band of wavelengths corresponding to the channel spacing. For example, see U.S. Pat. Nos. 5,546,209, 5,910,851, 6,307,660 and 6,556,321.

As a consequence, there is a need for a wavelength-dependent optical detector that can be dynamically tuned with a response time less than a few nanoseconds for WDM applications, and more generally with a response time less than a microsecond for other applications. It would also be advantageous if the wavelength-dependent optical detector could be dynamically tuned to resolve the narrow channel spacing in WDM systems yet have a wide tuning range. Furthermore, it would be advantageous if such a wavelength-dependent optical detector with fast dynamic tuning were electronically controlled using a low voltage thereby allowing ease of integration with other components.

### OBJECTS AND ADVANTAGES

In view of the above, it is a primary object of the present invention to provide an apparatus and method for a wavelength-dependent optical detector that can be dynamically tuned over a wide range with a response time of less than a few nanoseconds. More specifically, it is an object of the present invention to provide an electronically tuned, wavelength-dependent optical detector.

These and numerous other objects and advantages of the present invention will become apparent upon reading the following description.

### SUMMARY

The objects and advantages of the present invention are secured by an apparatus and method for an electronically tuned, wavelength-dependent optical detector. The electronically tuned, wavelength-dependent optical detector is a modified MSM photodetector. In the modified MSM device, a comb-like metal electrode, comprising at least five, substantially parallel arms with a fixed spacing from each other and having a common voltage, is deposited on a surface of a semiconductor. At least four metal electrodes, interdigitated with the comb-like metal electrode are also deposited on the surface of the semiconductor. Each of the metal electrodes is connected to a voltage means that applies a control voltage to each metal electrode. By applying a set of control voltages to the metal electrodes using the voltage means, a wavelength to be detected in a stream of light illuminating the modified MSM device is selected.

In one embodiment of the invention, the comb-like metal electrode in the modified MSM device is connected to an amplifier.

In another embodiment, an opaque coating is deposited on parts of the surface of the modified MSM device thereby grouping the arms of the comb-like metal electrode and the metal electrodes into pairs.

In another embodiment, the semiconductor in the modified MSM device is selected based on the wavelengths to be detected. GaAs is used for MSM devices in the 800 nm wavelength range. InAlAs deposited on InGaAs is used for MSM devices in the 1600 nm wavelength range.

In another embodiment, a plurality of modified MSM devices are used in an optical system where a stream of light comprised of multiple wavelengths is at least partially spatially segregated using a dispersion device.

In another embodiment, a standing wave generator is used to produce a spatially varying light intensity of the surface of the modified MSM device. By appropriately positioning the modified MSM device relative to the varying light intensity and applying a set of voltages to the metal electrodes using the voltage means, the wavelength to be detected is selected.

In another embodiment, the standing wave generator is an interferometer, and position of fringes in the spatially varying light intensity on the electronically tuned, wavelength-dependent optical detector is adjusted by varying the optical path-length difference in the interferometer. In addition, the wavelength spacing of the detected channels is adjusted by changing the optical path-length difference.

In another embodiment, the standing wave generator is an interferometer that interferes two beams separated by an angle on the MSM device, and the relative phase of the fringes in the spatially varying light intensity and the channel spacing is adjusted by varying the optical path-length difference in the interferometer.

In yet another embodiment, the standing wave generator is an interferometer that interferes two beams separated by an angle on the MSM device, and period of the fringes in the spatially varying light intensity is adjusted by varying the angle of incidence of the interfered beams.

A detailed description of the invention and the preferred and alternative embodiments is presented below in reference to the attached drawing figures.

### BRIEF DESCRIPTION OF THE FIGURES

FIG. 1 is a diagram illustrating a side view of an apparatus according to the invention.

FIG. 2 is a diagram illustrating a top view of an apparatus according to the invention.

FIG. 3 is a diagram illustrating a top view of another embodiment of an apparatus according to the invention.

FIG. 4 is a diagram illustrating a side view of another embodiment of an apparatus according to the invention.

FIG. 5 is a diagram illustrating an optical system incorporating an apparatus according to the invention.

FIG. 6 is a diagram illustrating an experimental set-up.

FIG. 7 is a diagram showing the measured photocurrent as a function of wavelength.

FIG. 8 is a diagram illustrating a biasing configuration relative to the fringes of an interference pattern for an apparatus according to the invention.

FIG. 9 is a diagram illustrating a biasing configuration relative to the fringes of two interference patterns for an apparatus according to the invention.

FIG. 10 is a diagram illustrating an experimental set-up.

### DETAILED DESCRIPTION OF THE EMBODIMENTS

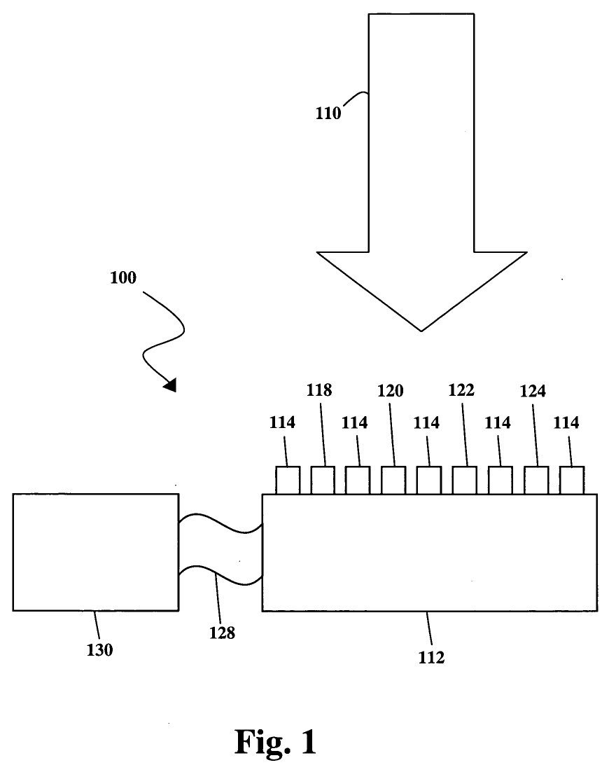

A side view of an embodiment of the invention is illustrated in FIG. 1. A stream of light 110 comprising at least one wavelength illuminates an electronically tuned, wavelength-dependent optical detector apparatus 100. The apparatus 100 is a modified MSM photodetector. The apparatus 100 has a comb-like metal electrode 114, comprising at least five, substantially parallel arms with a fixed spacing from each other and maintained at a common voltage. The parallel arms of metal electrode 114 are deposited on a surface of a semiconductor 112. At least four metal electrodes 118, 120, 122 and 124, interdigitated with the comb-like metal electrode 114 are also deposited on the surface of the semiconductor 112. Each of the metal electrodes 118, 120, 122 and 124 is connected by an electrical connection 128 to a voltage means 130, such as a power supply, that applies a control voltage to each metal electrode 118, 120, 122 and 124. In an alternative embodiment, the voltage means 130 is flip-chip bonded to the semiconductor 112. The stream of light 110 is absorbed in the semiconductor 112 producing charge carriers that drift to the neighboring metal electrodes 118, 120, 122 or 124 or the arms in the comb-like metal electrode 114 when the control voltage is applied to each of the metal electrode 118, 120, 122 and 124.

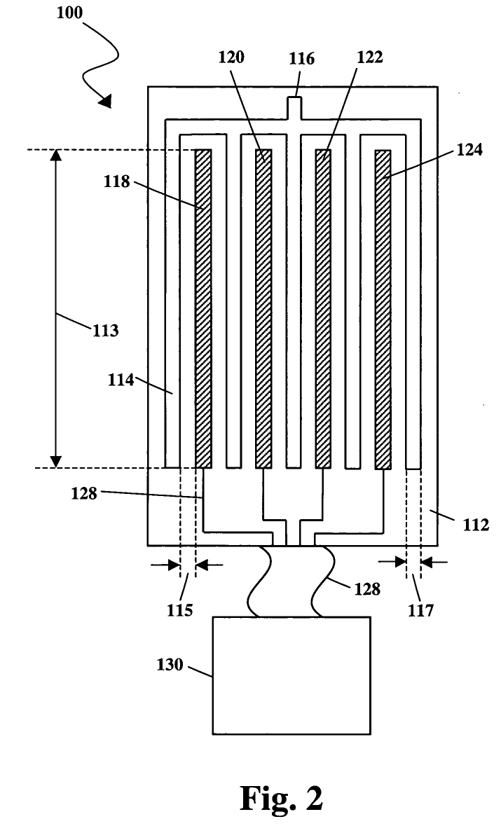

FIG. 2 illustrates a top view of the apparatus 100, with the comb-like metal electrode 114 deposited on the surface of the semiconductor 112. The comb-like metal electrode 114 has a common connection point 116. At least four metal electrodes 118, 120, 122 and 124, interdigitated with the comb-like metal electrode 114, are deposited on the surface of the semiconductor 112. The metal electrodes 118, 120, 122 and 124 are connected by the electrical connection 128 to the voltage means 130.

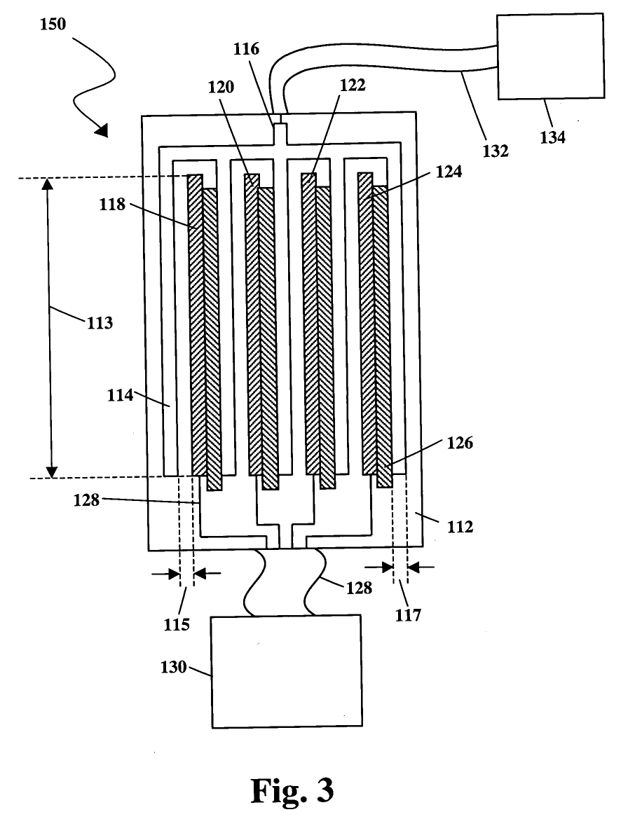

FIG. 3 illustrates a top view of alternative embodiments of apparatus 150. In this embodiment, an opaque coating 126 is deposited on the surface of the semiconductor 112 such that the arms in the comb-like metal electrode 114 are paired with one of the metal electrodes 118, 120, 122 and 124. Another alternative embodiment has an amplifier 134 connected 132 to the common connection point 116 of the comb-like metal electrode 114. In a preferred embodiment, the amplifier 134 is a trans-impedance amplifier. In yet another alternative embodiment, the amplifier 134 is flip-chip bonded to the semiconductor substrate 112.

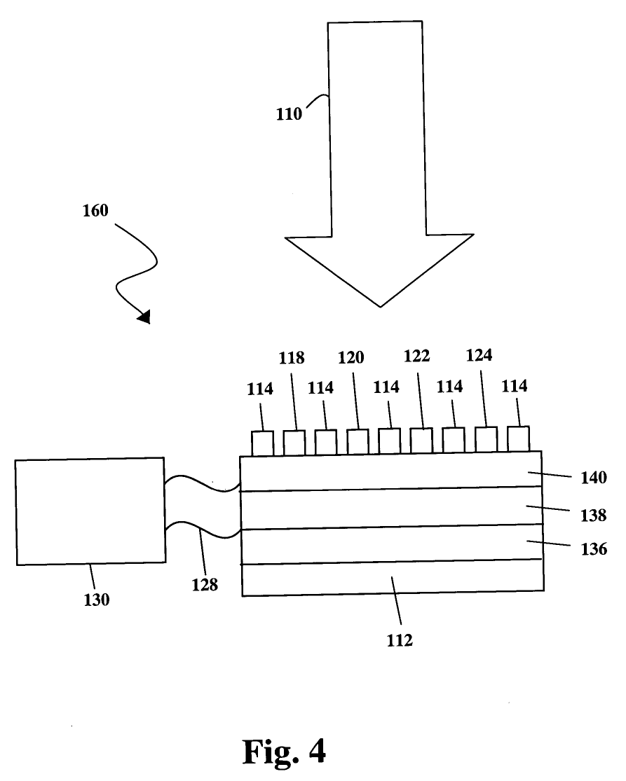

FIG. 4 illustrates a side view of alternative embodiments of apparatus 160. One alternative embodiment has an optional base layer 136, an optional intermediate layer 138 and an optional top layer 140 deposited in layers located above the surface of the semiconductor 112 and below the layer containing the comb-like metal electrode 114 and the metal electrodes 118, 120, 122 and 124. For wavelengths in the stream of light 110 less than 860 nm, a preferred embodiment has a semi-insulating GaAs semiconductor 112, a substantially 0.3 micron thick GaAs base layer 136 as a buffer, a substantially 0.3 micron AlGaAs intermediate layer 138 comprising relative proportions of substantially 85% aluminum and 15% gallium in the AlGaAs compound and being substantially 1 micron thick, and an undoped GaAs top layer 140 that functions as the active layer in the apparatus 160 absorbing the stream of light 110. The intermediate layer 138 in this embodiment serves two functions: it acts as an etch stop for etching through the semiconductor 112, thereby allowing flip-chip bonding of electronics such as the voltage means 130 and the amplifier 134 to the apparatus 160, and it acts as a barrier to keep carriers in the top layer 140 thereby improving temporal response of the apparatus 160 when stream of light 110 is absorbed in the top layer 140.

When the intermediate layer 138 is used as an etch stop layer, after flip-chip bonding of electronics such as the voltage means 130 and the amplifier means 134, the entire substrate layer 112 can be chemically removed using a selective etch or etches well known to those skilled in the art, with the etch substantially stopping when layer 138 is reached. In this case, stream of light 110 can impinge on the intermediate layer 138 from the bottom, which may be convenient since the flip-chip bonded electronics might otherwise get in the way of the stream of light 110 when the stream of light 110 is incident from above as shown in FIG. 4.

For wavelengths in the stream of light 110 substantially larger than 850 nm but less than 1650 nm, such as wavelength in the range 1200-1600 nm commonly used in telecommunications, a preferred embodiment has a semi-insulating InP semiconductor 112, an InP base layer 136 as a buffer, an undoped InGaAs intermediate layer 138 (comprising substantially 47% In and substantially 53% Ga and As) that functions as the active layer in the apparatus 160 absorbing the stream of light 110, and a thin InAlAs top layer 140 that increases the Schottky barrier height in the apparatus 160 and thereby reduces the leakage current that flows even when the stream of light 110 does not illuminate the apparatus 160.

Those skilled in the art will recognize that the details of the wafer structure can be modified for other applications of the invention in spectroscopy, optical interconnects, optical sensing and optical detection since the range of wavelength that can be detected with the apparatus 160 are confined to the absorption range of the semiconductor in the active layer of the apparatus 160.

As described thus far, the apparatus 160 cannot distinguish between two wavelengths so long as they are within the absorption range of the semiconductor in the active layer of the apparatus 160. For example, an apparatus with a GaAs active layer cannot distinguish 850 nm from 840 nm. To further distinguish the wavelength in the stream of light 110 to be detected in this invention, rapid, electronic tuning of the apparatus 160 occurs by varying the control voltage applied by the voltage means 130 to each of the metal electrodes 118, 120, 122 and 124. Temporal response of the apparatus 160 to a change in the control voltage is determined by resistance-capacitance (RC) time constant. For the apparatus 160 with the arms in the comb-like metal electrode 114 and the metal electrodes 118, 120, 122 and 124 having tens of micron length 113 (in FIGS. 2 and 3) and with micron spacing 115 (in FIGS. 2 and 3) between the arms in the comb-like metal electrode 114 and the metal electrodes 118, 120, 122 and 124, and width 117 of comb-like metal electrode 114 and the metal electrodes 118, 120, 122 and 124, capacitance of the apparatus 160 is less than several hundred fF. For the MSM device 100 in FIG. 2 with 0.8 micron electrode spacing 115 and width 117 and with interdigitated pattern covering total area of 100 micron length (not shown) by 52 micron width (not shown), the capacitance is theoretically 167.25 fF. For the MSM device 100 in FIG. 2 with 0.8 micron electrode spacing 115 and width 117 and with the interdigitated pattern covering total area of 40 micron length (not shown) by 26.4 micron width (not shown), the capacitance is theoretically 33.5 fF. Referring back to FIG. 4, in conjunction with low resistance of the apparatus 160, the temporal response of the apparatus 160 to change in the control voltage is less than a nanosecond. The rapid, electronic tuning of the apparatus 160 in this invention is further described below.

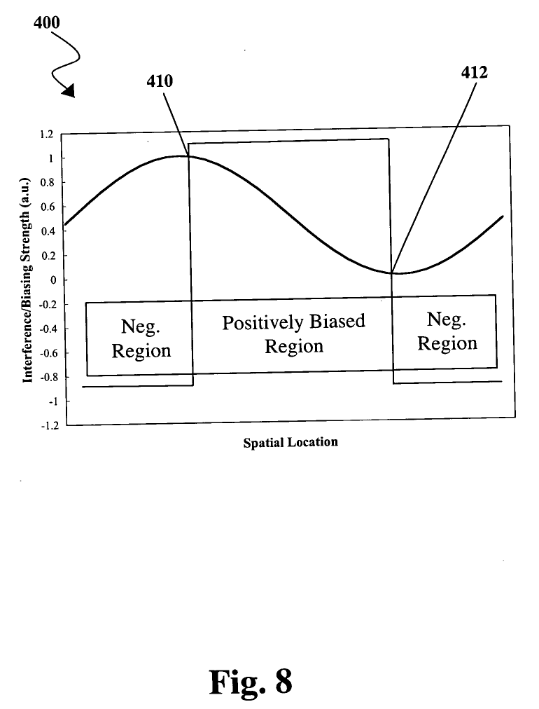

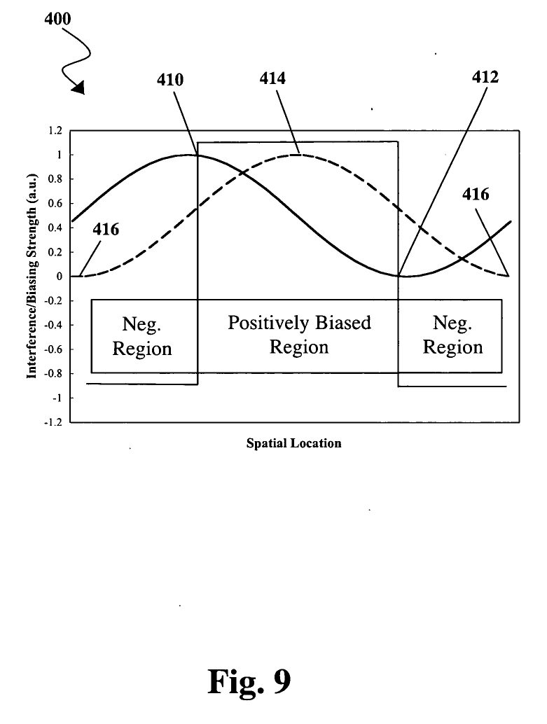

FIG. 8 schematically illustrates the electronic tuning of the wavelength in this invention. Here a spatially varying light intensity 400 corresponding to a wavelength in the beam of light 110 is shown on the surface of the apparatus 100 with a fringe spacing or separation between maxima 410 and minima 412 in the spatially varying light intensity that corresponds to four times the summation of the spacing 115 between and the width 117 of the comb-like metal electrode 114 and the metal electrodes 118, 120, 122 and 124 in the apparatus 100. Note that it is also important that the apparatus 100 be appropriately positioned relative to the spatially varying light intensity. In this example, the locations of the maxima 410 and the minima 412 in the spatially varying light intensity 400 are aligned with the locations of the comb-like metal electrode 114. If a negative control voltage is applied by the voltage means 130 to the metal electrodes 118 and 124, and a positive control voltage is applied by the voltage means 130 to the metal electrodes 120 and 122, the wavelength in the stream of light 110 that gives rise to the spatially varying light intensity 400 in FIG. 8 will give rise to zero net current and thus will not be detected. In contrast, the same control voltages will allow a neighboring wavelength with maxima 414 and minima 416, shown by the dashed line in FIG. 9, to produce a net current and therefore to be detected.

In principle, due to its symmetric structure, the current-voltage characteristic of the ideal electronically tuned, wavelength-dependent optical detector apparatus 100 has positive/negative symmetry with respect to the control voltage applied by the voltage means 130 to the metal electrodes 118, 120, 122 and 124. In practice, variations in fabrication may necessitate different voltages when wavelength-dependent optical detector apparatus 100 is illuminated by stream of light 110 with fringe intensity variation 400.

The detection of multiple wavelengths with a single apparatus 100 is enabled by this invention by increasing the number of metal electrodes 118, 120, 122 and 124 and the corresponding arms in the comb-like metal electrode 114 in the apparatus 100. The detection of multiple wavelengths with a single apparatus 100 is further enabled by appropriately positioning the apparatus relative to the spatially varying light intensity on the surface of the apparatus 100, i.e., by selecting the appropriate spatial phase relation, and by applying the appropriate control voltage to each metal electrode 118, 120, 122 and 124.

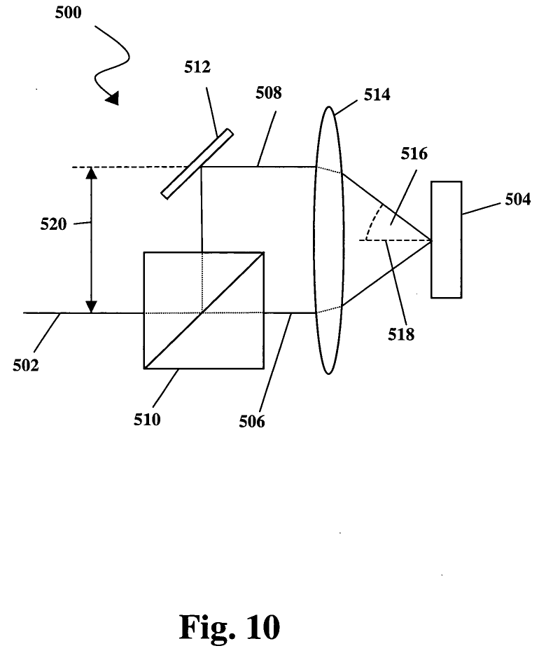

FIG. 10 illustrates in an exemplary embodiment how a standing wave generator such as an interferometer 500 is used to produce the spatially varying light intensity and to select relative phase of this spatially varying light intensity on wavelength dependent optical detector 504. A beam of light 502 is divided into two beams of light 506 and 508 by a beam splitter 510. Beam of light 508 is reflected off of mirror 512. Beams of light 506 and 508 pass through a lens 514 and are incident on the wavelength dependent optical detector 504 with an incident angle 516 relative to the normal 518 of the wavelength dependent optical detector 504. Beams of light 506 and 508 interfere due to a relative difference 520 in their optical path lengths. Such a path length difference 520 results in a time delay between the two beams 506 and 508 because of the additional time taken for light to propagate through the additional distance 520 in the path of beam of light 508. As a result of this delay and the incident angle 516 relative to the normal to the wavelength dependent optical detector 504, when the wavelength changes, the spatially varying light intensity substantially moves, corresponding to a change of the relative phase of the spatially varying light intensity. There is also a change in period of the spatially varying light intensity, although for small wavelength changes the variation in position of the spatially varying light intensity (and thus the relative phase) is more important for the operation of the wavelength-dependent optical detector 504. Additional means for forming such spatially varying light intensities on the surface of detectors with multiple elements are discussed in D. A. B. Miller, “Laser Tuners and Wavelength-Sensitive Detectors Based on Absorbers in Standing Waves,” IEEE Journal of Quantum Electronics, 30, 732-749 (1994), which is hereby incorporated by reference.

The dependence of the spacing between fringes in the spatially varying light intensity on the incident angle 516 of the two interfered beams of light 506 and 508 can be conceptually understood in terms of a plane wave with a fixed wavelength λ incident at an angle Ω relative to the normal of a flat mirror. The effective period of the standing wave pattern projected on the mirror is λ/sin(Ω). Since sin(Ω) is always less than one, if beams of light 506 and 508 are incident at incident angle 516 (equal to Ω) with respect to the wavelength dependent optical detector 504, the fringe width in the interference pattern, given by λ/(2 sin(Ω)), is increased compared to half a wavelength λ/2.

The theory behind the wavelength-dependent optical detector in this invention is described below for two illustrative examples.

Suppose we want the electronically tuned, wavelength-dependent optical detector in this invention to distinguish between two different wavelengths. As described above, the apparatus 100 with the comb-like metal electrode 114 and the four metal electrodes 118, 120, 122 and 124 is required. This is the minimum modified MSM device section size. Take the wavelength in the spatially varying light intensity aligned with the metal electrodes 118, 120, 122 and 124, such as that corresponding to the dashed curve 414 in FIG. 9, to be 860 nm. This is the wavelength to be detected. Metal electrodes 120 and 122 at the positive portions of the cycle corresponding to this wavelength have positive control voltage. Metal electrodes 118 and 124 at the negative portions of the cycle corresponding to this wavelength have negative control voltage. The relative phase between spatially varying intensity pattern for this wavelength and spatially varying intensity pattern for the neighboring wavelength that is not to be detected, such as the solid curve in FIGS. 8 and 9, is taken to be π/2. Furthermore, the neighboring wavelength that is not to be detected is taken to be 860.24 nm. For an arbitrary wavelength λ, constructive superposition at each metal electrode 118, 120, 122 and 124 requires
mλ=(m+φ/2π)860.
Taking m=896 as an illustrative example and rearranging we have
φ=2π[896(λ−860)/860].
The integrated intensity I over one period (0 to 2π) is I=I₁−I₂, where I₁∝∫(1+sin(θ−φ))dθ evaluated between 0 and π and I₂∝∫(1+sin(θ−φ))dθ evaluated between π and 2π. After some math, we find that
I∝4 cos(φ)=4 cos(2π[896(λ−860)/860]).
For λ=860 nm, I=1. For λ=860.24 nm, I=0. This value of I corresponds to φ=π/2, the phase shift between the two spatially varying light intensity patterns of the two wavelengths that we wished to discriminate between. Since the spatially varying light intensity pattern corresponding to the wavelength we wanted to detect (860 nm) is aligned with the metal electrodes 118, 120, 122 and 124, this result is tantamount to saying that the phase shift of the spatially varying light intensity pattern that we do not want to detect, i.e., the one corresponding to a wavelength of 860.24 nm, relative to the metal electrodes 118, 120, 122 and 124 is π/2. This, in turn, indicates the relative placement and biasing of the metal electrodes 118, 120, 122 and 124 in the apparatus 100 relative to the spatially varying light intensity corresponding to this wavelength. If we now wish to use the same detector to detect light of wavelength 860.24 nm and not detect light of wavelength 860 nm, we merely need to change the biasing of the fingers. Biasing metal electrodes 118 and 120 positively and metal electrodes 122 and 124 negatively will cause wavelength 860.24 nm to be detected and wavelength 860 nm not to be detected. This change in biasing corresponds to shifting the biasing pattern by a phase of π/2. Hence merely changing the biasing of the electrodes in the detector changes the wavelengths that it will detect and those that it will not detect.

To discriminate between 4 wavelengths (for example, 860 nm, 860.24 nm, 860.48 nm and 860.72 nm), a second minimum modified MSM device section is required. Thus, there are now 8 metal electrodes, where each of the MSM device sections has electrodes such as 118, 120, 122 and 124. One of the minimum modified MSM device sections is placed in the interference pattern between the beams such that the relative phase between the spatially varying intensity patterns of two adjacent wavelengths is π/4. The second minimum modified MSM device section is placed in the interference pattern between the beams such that the relative phase between the spatially varying intensity patterns of two adjacent wavelengths is 3π/4. Repeating the previous calculation with m=448 we find that
I∝cos(2π[448(λ−860)/860])+cos(2π[1344(λ−860)/860]).
For λ=860 nm, I=2. For λ=860.24 nm, I=0. For λ=860.48 nm, I=0. For λ=860.72 nm, I=0. Once again, the arguments of the cosine functions at the wavelengths that are not to be detected correspond to the relative phases between the spatially varying light intensities (in this example, multiples of π/4 and 3π/4). Once again, these phases indicate the relative placement and biasing of the metal electrodes, such as 118, 120, 122 and 124, in the apparatus 100 relative to the spatially varying light intensities corresponding to these wavelengths.

This invention can be generalized to discriminate between an arbitrarily large number of wavelengths. As such, this invention enables a wide tuning range. The results are summarized in Table I.

TABLE I
Generalized technique for electronically tuned, wavelength
detection using modified MSM optical detectors.

| Number of | Number of | Relative Phase | |
|---|---|---|---|
| Wavelengths | Minimum | (Where to Place | Number of |
| to be Dis- | MSM device | the MSM Device | Metal |
| criminated | Sections | Sections) | Electrodes |
| 2 | 1 | π2 | 4 |
| 4 | 2 | π/4, 3π/4 | 8 |
| 8 | 4 | π/8, 3π/8, 5π/8, 7π/8 | 16 |
| 2^{N} | 2^{N-1} | π/2^{N}, . . . , (2^{N} − 1)π/2^{N} | 2^{N+1} |

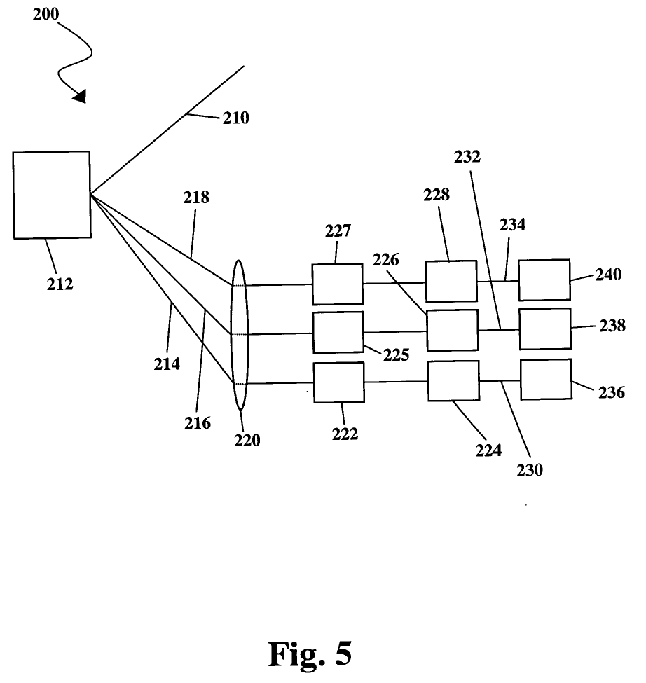

FIG. 5 shows an illustration of an embodiment of an optical system 200 that uses this invention. A stream of light 210 comprised of a plurality of wavelengths and containing information is at least partially spatially segregated by a dispersion device 212 into three optical beams 214, 216 and 218 each containing at least a wavelength and possibly a range of wavelengths. Suitable dispersion devices include, among others, a prism, a diffraction grating or an arrayed waveguide grating. The optical beams 214, 216 and 218 are collimated by a lens 220 and illuminated onto electronically tuned, wavelength-dependent optical detectors 224, 226 and 228, each of which is the same as the apparatus 160 as shown in FIG. 4. The optical detectors 224, 226, 228 are each connected 230, 232 and 234 to voltage means 236, 238 and 240. In an alternative embodiment, the voltage means 236, 238 and 240 are incorporated in the optical detectors 224, 226, 228. While this embodiment could use a standard photodetector that is neither wavelength-dependent nor dynamically tunable, such as those known in the prior art, the electronically tuned, wavelength-dependent optical detector of this invention still offers an advantage. In particular, the electronically tuned, wavelength-dependent optical detectors 224, 226 and 228 are able to detect the range of wavelengths in each beam 214, 216 and 218, thereby reducing the number of optical detectors 224, 226 and 228 in the optical system 200. In addition, in this example the dispersion device 212 provides coarse dispersion of the stream of light 210 and the optical detectors 224, 226 and 228 provide fine wavelength resolution. Standing wave generators 222, 225 and 227 are inserted between the lens 220 and optical detectors 224, 226 and 228 thereby producing a spatially varying light intensity on optical detectors 224, 226 and 228. Interferometer 500 is suitable for standing wave generators 222, 225 and 227. As described in the theory behind this invention described above, by appropriately positioning the spatially varying light intensity on optical detectors 224, 226 and 228 such that the metal electrodes 118, 120, 122 and 124 have the appropriate spatial phase relationship with the spatially varying light intensity and by applying the appropriate control voltage to each of the metal electrodes 118, 120, 122 and 124, particular wavelengths in the stream of light 210 can be selected for detection.

The interferometer 500 used as standing wave generators 222, 225 and 227 is also used to adjust the channel spacing. In an interferometer, a larger the optical path-length difference in the arms of the interferometer will result in a different phase for the fringes in the resultant interference pattern for a given wavelength since φ=2πnΔd/λ, where φ is the phase difference between the light in the arms of the interferometer that gives rise to the interference, n is the index of refraction, λ is the wavelength and Δd is the path-length difference. As described in the theory behind this invention described above, for discrimination between two wavelengths λ₁ and λ₂ a relative phase of π/2 is desired. In this case, the phase difference φ is

$$\frac{2 \cdot π \cdot n \cdot Δ d}{{λ}_{1}} - \frac{2 \cdot π \cdot n \cdot Δ d}{{λ}_{2}} = \frac{π}{2} .$$

Dividing both sides of this equation by 2π yields

$$n \cdot Δ d \cdot ( \frac{1}{{λ}_{1}} - \frac{1}{{λ}_{2}} ) = n \cdot Δ d \cdot ( \frac{{λ}_{2} - {λ}_{1}}{{λ}_{1} \cdot {λ}_{2}} ) = n \cdot Δ d \cdot ( \frac{Δλ}{{λ}_{1} \cdot {λ}_{2}} ) = \frac{1}{4} .$$

For telecommunication applications, wavelengths λ₁ and λ₂ are almost the same and can be taken to be approximately equal to wavelength λ, in this case the average of wavelengths λ₁ and λ₂. As a result, the required path length difference Δd is inversely proportional to 1/Δλ. Thus, increasing the optical-path length difference in the interferometer or the incident angle 516 of the beams of light 506 and 508 reduces the channel spacing. In addition, as mentioned previously in FIG. 10, the period of the fringes in the interference pattern is a function of the incident angle 516 given by λ/(2 sin(Ω)).

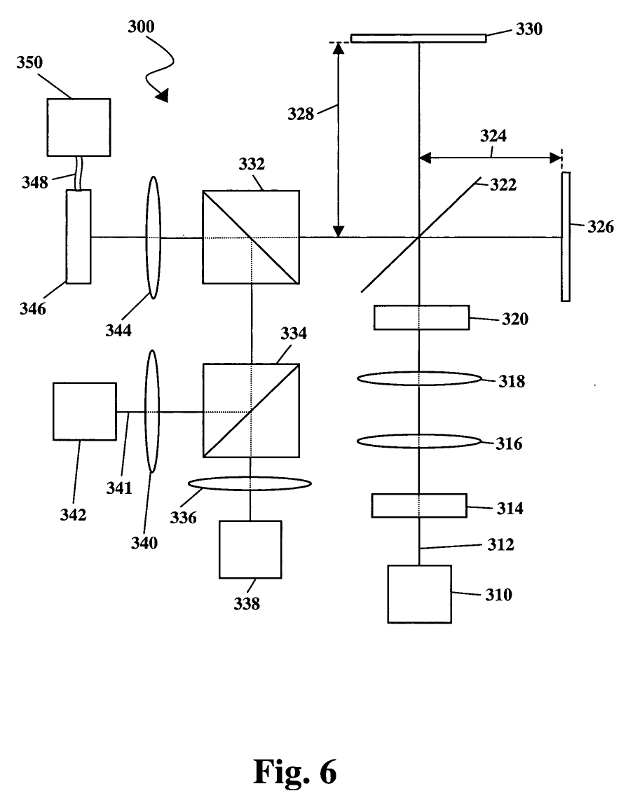

This embodiment of this invention is further illustrated in FIG. 6, which shows a schematic of the experimental setup 300 used to perform measurements with an electronically tuned, wavelength-dependent optical detector 346 of this invention. A stream of light 312 is produced by a light source 310. A tunable Ti-Sapphire laser is suitable. The light 312 passes through a chopper 314, to enable sensitive lock-in detection, and lenses 316 and 318, which determine the size of the interference pattern on the optical detector 346. The light 312 passes through an attenuator 320 and is directed along two paths in the Michelson interferometer by a 50/50 beam splitter 322. The two paths have path lengths 324 and 328. As noted above, the path length difference Δd, which is twice the difference of path lengths 324 and 328, partially determines the phase difference φ and the channel spacing. After reflecting off of mirrors 326 and 330, the light passes through a beam splitter 332, a focal lens 344 and illuminates optical detector 346. While not shown in FIG. 6, two beams in the stream of light 312 illuminate the optical detector 346 at an angle, as shown in FIG. 10, producing an interference pattern (not shown) on the optical detector 346. Referring back to FIG. 6, the angle between the two beams is controlled by tilting mirrors 326 and 330. In practice, the tilt, the path length difference Δd and wavelength λ₁ are fixed. As wavelength λ₂ varies, the relative phase is varied. The optical detector 346 is connected 348 to a voltage means 350. As disclosed in this invention, the position of the optical detector 346 relative to the fringes in the interference pattern is important. This is determined in this experimental setup 300 using an LED 342 to produce light 341 that is focused by a lens 340, passes through beam splitters 334 and 332, the focal lens 344 and illuminates the optical detector 346. The light reflected from the optical detector 346 passes through the focal lens 344, through the beam splitters 332 and 334, and is focused by a lens 336 onto a CCD camera 338.

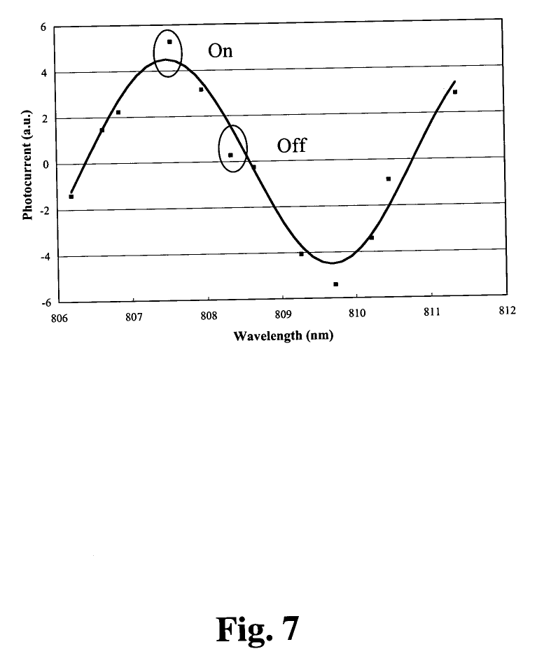

An electronically tuned, wavelength-dependent optical detector 346 of this invention has been fabricated where the spacing 115 and the width 117 of the comb-like metal electrode 114 and metal electrodes 118, 120, 122 and 124 are both 0.8 micron. The interdigitated pattern covers a 40 micron by 13.6 micron area. FIG. 7 shows the results of measurements performed using the optical detector 346 to distinguish two neighboring wavelengths. Positive control voltage of 2.1 V was applied to the metal electrodes 120 and 122 in the optical detector 346 by the voltage means 350 and negative control voltage of −1.25 V was applied to the metal electrodes 118 and 124 in the optical detector 346 by the voltage means 350 as illustrated schematically in FIGS. 8 and 9. The optical detector 346 is sensitive to the wavelength labeled “On” at 807.54 nm and is insensitive to the wavelength labeled “Off” at 808.33 nm. The theoretical sinusoidal response of the optical detector 346 is also shown. The demonstrated channel spacing of 0.76 nm is sufficient to enable a 365 GHz channel spacing in a WDM system. Additional experiments were able to resolve a channel spacing of 50 GHz. The channel spacing capability of the experimental setup 300 is limited by the line width and discontinuous tuning of the light source 310 not the capabilities of the optical detector 346.

The electronically tuned, wavelength-dependent optical detector in this invention has numerous advantages with respect to wavelength-dependent optical detectors in the prior art. It is capable of rapid tuning for multiple wavelengths with sub-nanosecond switching time. Electronic tuning is at low voltages (unlike devices with an external micro-machined optical filter) allowing easy integration with CMOS electronics. The wavelength-dependence is substantially insensitive to temperature variations (unlike devices with an external cavity-based optical filters). The channel spacing can be adjusted dynamically. The wavelength-dependence of the apparatus 100 is integrated into the apparatus 100, obviating the need for an external optical filter. And, finally, by adding additional metal electrodes 118, 120, 122 and 124 and arms to the comb-like metal electrode 114 the electronically tuned, wavelength-dependent optical detector is capable of a wide tuning range limited only by the absorption characteristics of the semiconductor in the active layer of the apparatus 100.

In view of the above, it will be clear to one skilled in the art that the above embodiments may be altered in many ways without departing from the scope of the invention. Accordingly, the scope of the invention should be determined by the following claims and their legal equivalents.

1. A wavelength-dependent, optical-signal detector, comprising:
a) a semiconductor substrate with a surface;
b) a comb-like metal electrode deposited in at least one layer located above said surface of said semiconductor substrate, said comb-like metal electrode comprising a plurality of arms at a common voltage;
c) a voltage means; and
d) a plurality of metal electrodes deposited in at least one layer located above said surface of said semiconductor substrate and interdigited between said arms of said comb-like metal electrode, said metal electrodes connected to said voltage means to provide each of said metal electrodes with a control voltage, said control voltage provided to each of said metal electrodes chosen to control collection and superposition of charge carriers produced in said wavelength-dependent, optical-signal detector by an optical signal, thereby selecting a wavelength to be detected with said wavelength-dependent, optical-signal detector.

2. The wavelength-dependent, optical-signal detector of claim 1 wherein said comb-like metal electrode and said metal electrodes are substantially coplanar.

3. The wavelength-dependent, optical-signal detector of claim 1 wherein said comb-like metal electrode further comprises at least five arms.

4. The wavelength-dependent, optical-signal detector of claim 1 wherein said metal electrodes further comprise at least four electrodes.

5. The wavelength-dependent, optical-signal detector of claim 1 further comprising at least one opaque masking layer deposited in at least one layer located above said surface of said semiconductor substrate such that a pair of electrodes, comprising one of said arms of said comb-like metal electrode and one of said metal electrodes, is separated from neighboring electrodes by said opaque masking layer.

6. The wavelength-dependent, optical-signal detector of claim 1 where in said semiconductor substrate is selected from the group consisting of GaAs and InP.

7. The wavelength-dependent, optical-signal detector of claim 1 further comprising a base layer, with a surface, deposited at a location above said surface of said semiconductor substrate and below said layer containing said comb-like metal electrode and said layer containing said metal electrodes.

8. The wavelength-dependent, optical-signal detector of claim 7 where in said base layer is selected from the group consisting of GaAs, InGaAs, AlGaAs and InP.

9. The wavelength-dependent, optical-signal detector of claim 7 further comprising an intermediate layer, with a surface, deposited at a location above said surface of said base layer and below said layer containing said comb-like metal electrode and said layer containing said metal electrodes.

10. The wavelength-dependent, optical-signal detector of claim 9 where in said intermediate layer is selected from the group consisting of InAlAs, GaAs, AlGaAs and InGaAs.

11. The wavelength-dependent, optical-signal detector of claim 9 further comprising a top layer deposited at a location above said surface of said intermediate layer and below said layer containing said comb-like metal electrode and said layer containing said metal electrodes.

12. The wavelength-dependent, optical-signal detector of claim 11 where in said top layer is selected from the group consisting of GaAs and InAlAs.

13. The wavelength-dependent, optical-signal detector of claim 1 wherein said voltage means comprises separate voltage sources for providing a separate control voltage to each of said metal electrodes.

14. The wavelength-dependent, optical-signal detector of claim 1 wherein said comb-like metal electrode is connected to an amplifier for amplifying.

15. The wavelength-dependent, optical-signal detector of claim 14 wherein said amplifier is a trans-impedance amplifier.

16. The wavelength-dependent, optical-signal detector of claim 1 wherein production of said charge carriers in response to said optical signal in production of said charge carriers in response to said optical signal in other regions in said wavelength-dependent, optical-signal detector is disabled.

17. The wavelength-dependent, optical-signal detector of claim 16 wherein a standing wave pattern obtained from said optical signal enables and disables production of charge carriers in response to said optical signal in said regions and said other regions in said wavelength-dependent, optical-signal detector.

18. The wavelength-dependent, optical-signal detector of claim 17 wherein an interferometer produces said standing wave pattern.

19. The wavelength-dependent, optical-signal detector of claim 17 wherein said standing wave pattern is positioned relative to said metal electrodes and said comb-like metal electrode to enable detection of said wavelength in said wavelength-dependent, optical-signal detector.

20. An optical system, comprising:
a) a stream of light with a plurality of wavelengths containing information; and
b) at least one wavelength-dependent detector having a set of electrodes for switching between wavelengths, wherein charge carriers produced by said stream of light in said wavelength-dependent detector are collected and superposed in response to a set of control voltages applied to said set of electrodes in said wavelength-dependent detector by a voltage means, wherein a wavelength to be detected predetermines said set of control voltages applied to said set of electrodes.

21. The optical system of claim 20 wherein RC time constant of said wavelength-dependent detector provides for switching between wavelengths in less than 10 ns.

22. The optical system of claim 20 further comprising at least one amplifier.

23. The optical system of claim 22 wherein said amplifier is a trans-impedance amplifier.

24. The optical system of claim 20 further comprising at least one dispersion device for spatially segregating said light stream.

25. The optical system of claim 24 wherein said dispersion device is selected from the group consisting of a diffraction grating, a prism and an array waveguide grating.

26. The optical system of claim 20 further comprising a plurality of wavelength-dependent detectors, each of which is used to detect a range of wavelengths.

27. The optical system of claim 20 further comprising at least one lens to focus said stream of light onto said wavelength-dependent detector.

28. The optical system of claim 20 further comprising at least one standing-wave generator for generating a wavelength-dependent, spatially varying light intensity.

29. The optical system of claim 28 wherein angle of incidence of at least two beams in said stream of light to said wavelength-dependent detector determines position and period of said spatially varying light intensity relative to said set of electrodes in said wavelength-dependent detector.

30. The optical system of claim 28 wherein said standing-wave generator is an interferometer.

31. The optical system of claim 30 wherein optical path length difference in said interferometer determines position of said spatially varying light intensity relative to said set of electrodes in said wavelength-dependent detector.

32. The optical system of claim 30 wherein channel spacing is determined by path length difference in said interferometer.

33. The optical system of claim 20 wherein information in said stream of light is encoded with a technique selected from the group consisting of time domain multiplexing, frequency domain multiplexing, time domain and frequency domain multiplexing, spread-spectrum encoding and iterative coding.

34. The optical system of claim 33 wherein spread-spectrum encoding is code division multiple access.

35. The optical system of claim 20 wherein said optical system is at least part of a system selected from the group consisting of DWDM, CWDM, WDM, a spectrometer, an optical interconnect and an optical sensor.

36. The optical system of claim 20 wherein said wavelength-dependent detector comprises:
a) a semiconductor substrate with a surface;
b) a comb-like metal electrode deposited in a layer located above said surface of said semiconductor substrate, said comb-like metal electrode comprising at least five arms at a common voltage;
c) a voltage means;
d) at least four metal electrodes deposited in a layer located above said surface of said semiconductor substrate, substantially coplanar with said comb-like metal electrode and interdigited between said arms of said comb-like metal electrode, each of said metal electrodes connected to said voltage means which provides said set of control voltages to said metal electrodes; and
e) a trans-impedance amplifier connected to said comb-like metal electrode.

37. The optical system of claim 36 further comprising at least one opaque masking layer deposited in a layer located above said surface of said semiconductor substrate such that a pair of electrodes, comprising one of said arms of said comb-like metal electrode and one of said metal electrodes, is separated from neighboring electrodes by said opaque masking layer.

38. The optical system of claim 36 wherein said voltage means comprises separate voltage sources for providing a separate control voltage in said set of control voltages to each of said metal electrodes.

39. The optical system of claim 38 wherein said semiconductor substrate is taken from the group consisting of GaAs and InP.

40. The optical system of claim 36 further comprising a base layer, with a surface, deposited at a location above said surface of said semiconductor substrate and below said layer containing said comb-like metal electrode and said layer containing said metal electrodes.

41. The optical system of claim 40 where in said base layer is taken from the group consisting of GaAs, InGaAs, AlGaAs and InP.

42. The optical system of claim 40 further comprising an intermediate layer, with a surface, deposited at a location above said surface of said base layer and below said layer containing said comb-like metal electrode and said layer containing said metal electrodes.

43. The optical system of claim 42 where in said intermediate layer is taken from the group consisting of InAlAs, GaAs, AlGaAs and InGaAs.

44. The wavelength-dependent, optical-signal detector of claim 42 further comprising a top layer deposited at a location above said surface of said intermediate layer and below said layer containing said comb-like metal electrode and said layer containing said metal electrodes.

45. The wavelength-dependent, optical-signal detector of claim 44 where in said top layer is selected from the group consisting of GaAs and InAlAs.

46. A method of detecting a wavelength of light with a wavelength-dependent detector, comprising:
a) illuminating said wavelength-dependent detector with said light containing said wavelength;
b) connecting said wavelength-dependent detector to a voltage means; and
c) setting a control voltage on each of a plurality of metal electrodes interdigitated with a plurality of arms in a comb-like metal electrode in said wavelength-dependent detector with said voltage means, said control voltage set on each of said metal electrodes controlling collection and superposition of charge carriers produced in said wavelength-dependent detector by said light, thereby selecting said wavelength.

47. The method of claim 46 further comprising the step of connecting said comb-like metal electrode in said wavelength-dependent detector to an amplifier.

48. The method of claim 46 further comprising the step of selecting said wavelength of said light by spatially segregating said light with a dispersion device.

49. The method of claim 46 further comprising the step of producing a spatially varying intensity of said light on said wavelength-dependent detector by passing said light through an interferometer.

50. The method of claim 49 further comprising the step of setting position and period of said spatially varying light intensity relative to said metal electrodes in said wavelength-dependent detector by adjusting angle of incidence of at least two beams in said light to said wavelength-dependent detector.

51. The method of claim 49 further comprising the step of setting position and period of said spatially varying light intensity relative to said metal electrodes in said wavelength-dependent detector by adjusting optical path length difference in said interferometer.

52. The method of claim 49 further comprising the step of adjusting channel spacing by changing path length difference in said interferometer.
